(19) United States
(12) Patent Application Publication
(10) Pub. No.: US 2009/0141913 A1
(43) Pub. Date: Jun. 4, 2009

(54) MICROELECTROMECHANICAL SYSTEM

(76) Inventors: Michael MAUER, Kirchheim (DE); Heinrich HEISS, Munich (DE)

Correspondence Address: INFINEON TECHNOLOGIES AG;Patent Department, MUC 11.1.507, P.O. Box 221644, Munich, 80506, DE

(21) Appl. No.: 12/324,864

(22) Filed: Nov. 27, 2008

(30) Foreign Application Priority Data
Nov. 29, 2007 (DE) 102007057492.6

(51) Int. Cl. H04R 19/04; H01L 29/84; H01L 21/58

(52) U.S. Cl. 381/174; 257/415; 438/51; 257/E21.505; 257/E29.324

(57) ABSTRACT

A microelectromechanical system comprises a carrier substrate. A semiconductor chip is fitted in the carrier substrate or on the carrier substrate. In addition, a microelectromechanical component is fitted to the carrier substrate. The microelectromechanical component is arranged at least partly above the semiconductor chip.

### RELATED APPLICATIONS

This application claims priority to German Patent Application No. 10 2007 057 492 filed on Nov. 29, 2007, which is incorporated herein by reference in its entirety.

### TECHNICAL FIELD

Exemplary embodiments of the invention relate to a microelectromechanical system and methods for producing such a system.

### BACKGROUND

Microelectromechanical components, such as e.g. sensors/actuators, are often assembled in combination with electronic circuits alongside one another on a substrate to form microelectromechanical systems (MEMS). Examples of applications for MEMS are pressure sensors, acceleration sensors, microphones or light-generating elements. By virtue of the components arranged alongside one another, MEMS have hitherto occupied a great deal of space.

### SUMMARY

Exemplary embodiments of the invention are concerned hereinafter with microelectromechanical systems which take up less space than conventional components.

The invention is characterized by the independent claims. Developments of the invention are found in the dependent claims.

Embodiments of the invention relate generally to a microelectromechanical system comprising a carrier substrate, a semiconductor chip fitted in the carrier substrate or on the carrier substrate, and a microelectromechanical component fitted to the carrier substrate, wherein the microelectromechanical component is arranged at least partly above the semiconductor chip.

Specifically, embodiments of the invention relate to a microphone module, comprising a carrier substrate, a semiconductor chip having an integrated circuit for processing an electrical signal and a microphone for converting acoustic signals into electrical signals, wherein the semiconductor chip is arranged in the carrier substrate or on the carrier substrate and wherein the microphone is fitted to the carrier substrate at least partly above the semiconductor chip and is electrically connected to the semiconductor chip.

Furthermore, embodiments of the invention relate to methods for producing a microelectromechanical system.

In this case, one method involves providing a carrier substrate, fitting a semiconductor chip to the carrier substrate, and fitting a microelectromechanical component to the carrier substrate at least partly above the semiconductor chip.

Another method involves providing a first part of a carrier substrate, fitting a semiconductor chip to the first part of the carrier substrate, fitting a second part of the carrier substrate to the first part and above the semiconductor chip, and fitting a microelectromechanical component to the carrier substrate, at least partly above the semiconductor chip.

### BRIEF DESCRIPTION OF THE FIGURES

Exemplary embodiments of the invention are explained in more detail below with reference to the accompanying figures. However, the invention is not restricted to the specifically described embodiments, but rather can be modified and altered in a suitable manner. It lies within the scope of the invention to suitably combine individual features and combinations of features of one embodiment with features and combinations of features of another embodiment in order to arrive at further embodiments according to the invention.

Before the exemplary embodiments of the present invention are explained in more detail below with reference to the figures, it is pointed out that identical elements in the figures are provided with the same or similar reference symbols, and that a repeated description of these elements is omitted.

FIG. 1 shows a schematic cross-sectional view of an MEMS.

FIG. 2 shows a schematic cross-sectional view of a microphone module.

FIG. 3 shows a schematic cross-sectional view of a further microphone module.

FIG. 4 shows a schematic cross-sectional view of a further microphone module.

FIG. 5 shows a schematic cross-sectional view of a further microphone module.

FIG. 6 shows a schematic cross-sectional view of a further microphone module.

### DETAILED DESCRIPTION

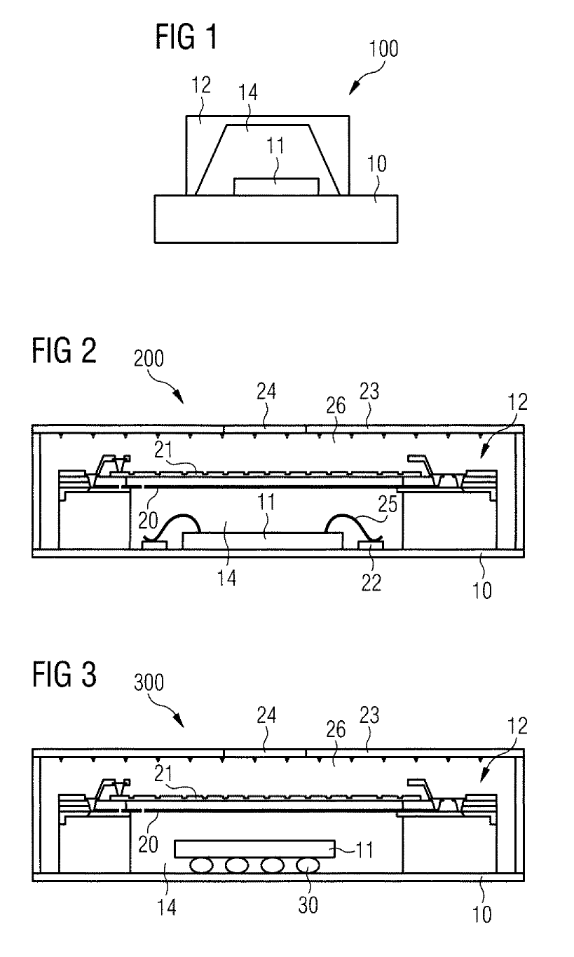

FIG. 1 illustrates a microelectromechanical system (MEMS) 100 in cross section as an exemplary embodiment of the invention. The microelectromechanical system 100 can be e.g. a capacitive transducer (acceleration sensor, pressure sensor, microphone, etc.) or a light-generating element.

The microelectromechanical system 100 has a carrier substrate 10. The carrier substrate 10 can e.g. be produced on a semiconductor basis or comprise some other material, e.g. ceramic, glass or polymer. The carrier substrate 10 can also be a PCB (Printed Circuit Board) or a leadframe produced from copper. The carrier substrate 10 can additionally be composed of a plurality of layers, in particular of a plurality of layers made of different materials.

A semiconductor chip 11 is fitted on the carrier substrate 10. As an alternative, the semiconductor chip 11 can also be fitted in the carrier substrate 10.

In one embodiment, the semiconductor chip 11 can be arranged e.g. in a cut-out produced in the carrier substrate 10. A further embodiment provides for the semiconductor chip 11 to be arranged above a cut-out of the carrier substrate 10 and to be connected to the carrier substrate 10 by contact elements in the cut-out. Yet another embodiment provides for the semiconductor chip 11 to be arranged in a cavity in the carrier substrate 10. In the case of a multi-layered carrier substrate 10, the semiconductor chip 11 can be embedded for example between two layers.

In addition, a microelectromechanical component 12 is fitted to the carrier substrate 10. In this case, the microelectromechanical component 12 is arranged at least partly above the semiconductor chip 11.

In one embodiment, the microelectromechanical component 12 can be electrically connected to the semiconductor chip 11.

The semiconductor chip 11 has an integrated circuit and can serve for example for picking up electrical signals generated by the microelectromechanical component 12 and for processing them further or for controlling the microelectromechanical component 12. The semiconductor chip 11 can be an ASIC (Application Specific Integrated Circuit) that is designed specifically for its application with regard to the further processing of the electrical signals and/or the driving of the microelectromechanical component 12.

In one embodiment of the invention, the microelectromechanical component 12 together with the carrier substrate 10 can delimit a volume 14. This volume 14, e.g. in the case of a microphone, can form a closed-off back volume that prevents an acoustic short circuit, i.e. an undesired pressure equalisation between front side and rear side of a vibrating diaphragm. Upon each deflection of the diaphragm, said back volume brings about a restoring force in addition to the restoring force caused by the elastic diaphragm properties.

A further embodiment of the invention provides for the semiconductor chip 11 to be arranged at least partly in the volume 14.

Further exemplary embodiments can provide a protection device arranged on the carrier substrate 10, wherein the protection device delimits together with the carrier substrate 10 a volume in which at least the microelectromechanical component 11 is at least partly arranged.

FIG. 2 shows an MEMS 200 representing a development of the MEMS 100 shown in FIG. 1. In the case of the MEMS 200, the microelectromechanical component 12 is embodied as a microphone, for example for a capacitive transducer. The microphone 12 has a moveable diaphragm 20 as a first electrode and a perforated counter electrode 21. The microphone 12 serves for converting acoustic signals into electrical signals. The microphone 12, generally a silicon microphone produced from silicon base material, is fitted on the carrier substrate 10. The carrier substrate 10 has for example conductor track structures at its surface. At contact locations of said conductor track structures, the microphone is electrically contact-connected to the carrier substrate by means of bonding wires or using flip-chip technology (not illustrated).

The microphone 12 forms together with the carrier substrate 10 a volume 14 serving as a back volume for the microphone. In this volume, a semiconductor chip 11 is arranged on the carrier substrate 10, which semiconductor chip is electrically connected via bonding wires 25 to further contact locations 22 of the conductor track structures at the surface of the carrier substrate 10. The semiconductor chip 11 is therefore electrically connected to the microphone 12 via the conductor track structures and performs for example the tasks already explained with regard to FIG. 1.

A protection device 23 is fitted to the carrier substrate 10 over the arrangement comprising microphone 12 and semiconductor chip 11. The protection device 23 has an acoustically transmissive opening 24 that enables a sound pressure wave to pass to the microphone 12.

FIG. 3 shows an MEMS 300 likewise representing a development of the MEMS 100 shown in FIG. 1. In contrast to the MEMS 200 from FIG. 2, the MEMS 300 has a semiconductor chip 11 in the volume 14 formed by the microphone 12 and the carrier substrate 10, wherein the semiconductor chip 11 is fitted on the carrier substrate 10 by means of contact elements 30 using flip-chip technology.

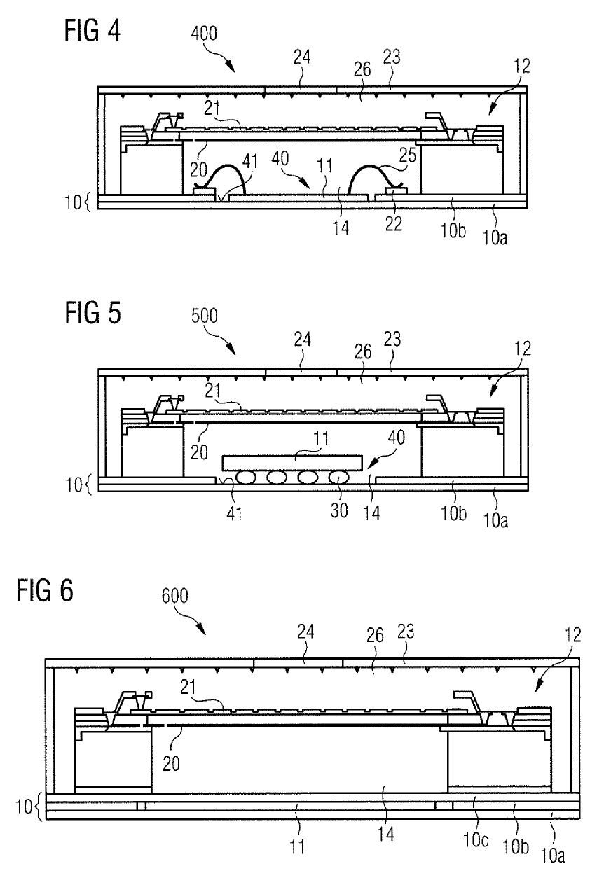

FIG. 4 illustrates an MEMS 400 representing a development of the MEMS 200 shown in FIG. 2. In this embodiment, the semiconductor chip 11 is arranged in a cut-out 40 of the carrier substrate 10 and is electrically connected by means of bonding wires 25 to the further contact locations 22 of the conductor track structures at the surface of the carrier substrate 10. In this case, the carrier substrate 10 is constructed from 2 layers 10a and 10b, wherein the second layer 10b has an interruption and forms the cut-out 40 of the carrier substrate 10. The surface 41 of the first layer 10a is exposed through said cut-out 40. The semiconductor chip 11 is fitted to said surface 41.

FIG. 5 illustrates an MEMS 500 representing a development of the MEMS 300 shown in FIG. 3. In this exemplary embodiment, the semiconductor chip 11 is arranged above the cut-out 40 of the carrier substrate 10 and is connected to the carrier substrate 10 by contact elements 30 in the cut-out 40. In this case, as already illustrated in FIG. 4, the carrier substrate 10 is constructed from 2 layers 10a and 10b, wherein the second layer 10b has an interruption and forms the cut-out 40 of the carrier substrate 10. The surface 41 of the first layer 10a is exposed through said cut-out 40. The semiconductor chip 11 is fitted to said surface 41.

FIG. 6 illustrates an MEMS 600 showing a further embodiment of the MEMS according to the invention. The MEMS 600 has a semiconductor chip 11, a microphone 12, a carrier substrate 10 constructed from three layers 10a, 10b and 10c, and a protection device 23 having an acoustically transmissive opening 24. In contrast to the previously described embodiments of the invention, the semiconductor chip 11 in this embodiment is embedded between the two layers 10a and 10c in the carrier substrate 10. In this case, the semiconductor chip 11 is fitted in a prefabricated first part of the carrier substrate 10, comprising the layers 10a and 10b, in the cut-out of the layer 10b. A second part of the carrier substrate 10, in this case the layer 10c, is subsequently fitted to the first part and above the semiconductor chip 11.

The semiconductor chip 11 (with contact elements possibly present) has at most the same thickness as the layer 10b, in order that it is completely recessed in the cut-out of the layer 10b, and the third layer 10c can be placed over the semiconductor chip 11 in planar fashion.

The embodiments described are intended to explain the invention merely by way of example. In particular, other MEMS can also be used instead of a microphone. Moreover, arrangements from one exemplary embodiment can also be applied to other exemplary embodiments.

1. A microelectromechanical system comprising:
a carrier substrate;
a semiconductor chip coupled to the carrier substrate; and
a microelectromechanical component coupled to the carrier substrate at least partly above the semiconductor chip.

2. The microelectromechanical system of claim 1, wherein the semiconductor chip is arranged in a cut-out in the carrier substrate.

3. The microelectromechanical system of claim 1, wherein the semiconductor chip is arranged above a cut-out in the carrier substrate and is coupled to the carrier substrate by contact elements in the cut-out.

4. The microelectromechanical system of claim 1, wherein the semiconductor chip is arranged in a cavity in the carrier substrate.

5. The microelectromechanical system of claim 1, wherein the carrier substrate comprises a plurality of layers.

6. The microelectromechanical system of claim 5, wherein the semiconductor chip is embedded between two layers.

7. The microelectromechanical system of claim 1, wherein the microelectromechanical component and the carrier substrate define a volume.

8. The microelectromechanical system according to claim 7, wherein the semiconductor chip is arranged at least partly in a cavity in the carrier substrate.

9. The microelectromechanical system of claim 1, wherein the microelectromechanical component comprises a capacitive transducer.

10. The microelectromechanical system of claim 9, wherein the capacitive transducer is a microphone.

11. The microelectromechanical system of claim 9, wherein the capacitive transducer is a pressure sensor.

12. The microelectromechanical system of claim 1, wherein the semiconductor chip is electrically connected to the microelectromechanical component.

13. The microelectromechanical system of claim 1, wherein a protection device is arranged on the carrier substrate, and wherein the protection device and the carrier substrate define a volume in which at least the microelectromechanical component is at least partly arranged.

14. The microelectromechanical system of claim 13, wherein the protection device comprises at least one opening.

15. A method for producing a microelectromechanical system comprising:
providing a carrier substrate;
coupling a semiconductor chip to the carrier substrate; and
coupling a microelectromechanical component to the carrier substrate at least partly above the semiconductor chip.

16. The method of claim 15, further comprising:
forming a cut-out in the carrier substrate, wherein the semiconductor chip is fitted to the carrier substrate in the cut-out.

17. A method for producing a microelectromechanical system comprising:
providing a first part of a carrier substrate;
coupling a semiconductor chip to the first part;
coupling a second part of the carrier substrate to the first part and above the semiconductor chip; and
coupling a microelectromechanical component to the carrier substrate at least partly above the semiconductor chip.

18. The method of claim 17, further comprising coupling a protection device to the carrier substrate at least partly above the microelectromechanical component.

19. The method of claim 17, wherein the semiconductor chip and the microelectromechanical component are electrically connected.

20. A microphone module comprising:
a carrier substrate;
a semiconductor chip having an integrated circuit configured to process electrical signals, wherein the semiconductor chip is arranged in or on the carrier substrate; and
a microphone configured to convert acoustic signals into electrical signals, wherein the microphone is fitted to the carrier substrate at least partly above the semiconductor chip and is electrically connected to the semiconductor chip.
